(19) United States
(12) Patent Application Publication
(10) Pub. No.: US 2025/0316502 A1
(43) Pub. Date: Oct. 9, 2025

(54) MONOLITHIC GAS DISTRIBUTION ASSEMBLY FOR PROCESS CHAMBERS

(71) Applicant: APPLIED MATERIALS, INC., Santa Clara, CA (US)

(72) Inventors: Hari Kishen Ponnekanti, San Jose, CA (US); Tom Cho, Los Altos, CA (US); Chien-Min Liao, San Jose, CA (US); Gregory Phillip Lim, Fremont, CA (US); Chao Liu, San Jose, CA (US)

(21) Appl. No.: 18/628,421

(22) Filed: Apr. 5, 2024

(51) Int. Cl. H01L 21/67; B33Y 10/00; B33Y 70/00

(52) U.S. Cl. CPC H01L 21/67017; B33Y 10/00; B33Y 70/00

(57) ABSTRACT

A monolithic gas distribution assembly includes a first portion configured to receive a low of process gas. The gas distribution assembly further includes a second portion forming a first plenum at least partially between the first portion and the second portion. The first portion forms one or more first gas paths to distribute the flow of process gas into the first plenum. The gas distribution assembly further includes a third portion forming a second plenum at least partially between the second portion and the third portion. The second portion forms one or more second gas paths to distribute the flow of process gas from the first plenum into the second plenum. The third portion further forms one or more third gas paths to distribute the flow of process gas from the second plenum into a process chamber. The first portion, the second portion, and the third portion form a single monolithic body.

### TECHNICAL FIELD

The present disclosure relates, in general, to a monolithic gas distribution assembly for process chambers. In particular, the present disclosure relates to a gas distribution assembly having integrated components that form a single monolithic body and methods of manufacturing the same.

### BACKGROUND

Semiconductor substrates are commonly processed in processing systems. These systems include one or more processing chambers, each performing substrate processing operations such as etching, chemical vapor deposition, or physical vapor deposition, which can include temperature and pressure cycling as well as introduction of a variety of chemical components into the chambers. Each of the processing chambers include an assembly to distribute process gases within the chamber. Such assemblies are typically made up of multiple pieces with seals between each of the pieces that can fail.

### SUMMARY

In an aspect of the disclosure, a monolithic gas distribution assembly includes a first portion configured to receive a low of process gas. The monolithic gas distribution assembly further includes a second portion forming a first plenum at least partially between the first portion and the second portion. The first portion forms one or more first gas paths to distribute the flow of process gas into the first plenum. The monolithic gas distribution assembly further includes a third portion forming a second plenum at least partially between the second portion and the third portion. The second portion forms one or more second gas paths to distribute the flow of process gas from the first plenum into the second plenum. The third portion further forms one or more third gas paths to distribute the flow of process gas from the second plenum into a process chamber. The first portion, the second portion, and the third portion form a single monolithic body.

In another aspect of the disclosure, a method includes forming a first portion of a gas distribution assembly. The first portion forms one or more first gas paths. The method further includes forming a second portion of the gas distribution assembly. The second portion at least partially forms a first plenum between the first portion and the second portion. The second portion forms one or more second gas paths. The method further includes forming a third portion of the gas distribution assembly. The second portion at least partially forms a second plenum between the third portion and the second portion. The third portion forms one or more third gas paths. The first portion, the second portion, and the third portion form a single monolithic body.

In a further aspect of the disclosure, a process chamber includes a gas distribution assembly including a single monolithic body having multiple integrated components. The multiple integrated components form at least one interior plenum and multiple gas paths configured to receive one or more process gases and distribute the one or more process gases substantially uniformly within the process chamber.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of a manufacturing chamber, according to certain embodiments of the present disclosure.

FIGS. 2A-2B depicts monolithic gas distribution assemblies, according to certain embodiments of the present disclosure.

FIG. 3 depicts a bottom perspective view of a showerhead, according to certain embodiments of the present disclosure.

FIG. 4A illustrates a flow chart of a method for manufacturing a monolithic gas distribution assembly, according to certain embodiments of the present disclosure.

FIG. 4B illustrates a flow chart of a method for re-conditioning a monolithic gas distribution assembly, according to certain embodiments of the present disclosure.

### DETAILED DESCRIPTION OF EMBODIMENTS

Embodiments described herein cover a monolithic gas distribution assembly for process chambers and a method for manufacturing the same.

Conventionally, gas distribution assemblies are made up of multiple component pieces which are fastened together. These multiple components or pieces, when assembled, make up what is often called a “lid stack.” For example, a conventional gas distribution assembly may include a gas box, a blocker plate, and a face plate or showerhead arranged in a stacked orientation. Each of the individual components in a conventional gas distribution assembly are independently manufactured and then assembled together, often using mechanical fasteners to couple the parts together. The gas box may be for receiving a flow of process gas, the blocker plate may be for distributing the gas radially, and the showerhead may be for distributing the gas uniformly to substrate(s) disposed on substrate support(s) inside the process chamber. Some of the components (e.g., gas box, blocker plate, showerhead, etc.) may form plenums between the components to facilitate the flow and/or distribution of process gas. Often, conventional gas distribution assemblies are exposed to corrosive process gases which ultimately affect the assembly components themselves.

Typically, seals such as o-ring seals are included between each of the components of a conventional gas distribution assembly. These seals can degrade over time and eventually fail, causing leaks of potentially harmful and/or hazardous process gases and compromising the ability of the process chamber to accurately and/or effectively process substrates. Additionally, o-rings are often temperature-limited, meaning that the temperature of a conventional gas distribution assembly is to remain below a threshold temperature so as not to compromise the o-rings.

To perform maintenance on a process chamber, the gas distribution assembly is often removed. Because conventional gas distribution assemblies are made up of multiple components, disassembly and reassembly can be a lengthy process. Additionally, proper reassembly of conventional gas distribution assemblies takes extra time to realign the separate components together and to verify that the joints between components do not leak.

Aspects and implementations of the instant disclosure address the above-described and other shortcomings of conventional systems by providing a monolithic gas distribution assembly for a process chamber. In some embodiments, the gas box, blocker plate, and showerhead of a gas distribution assembly are integrated into a single monolithic body, at least a portion of which may be made of corrosion-resistant materials. The monolithic gas distribution assembly described herein may be capable for use in process chambers that perform plasma-enhanced fluorinated etching. The monolithic gas distribution assembly described herein may be beneficial in areas such as thermal expansion, reduced time for assembly and/or maintenance, and maintenance or reconditioning of the assembly itself. In some embodiments, the monolithic gas distribution assembly described herein may be selectively made up of material to enhance the assembly's resistance to corrosion. In some embodiments, regions of the monolithic gas distribution assembly that are exposed to process gases are composed of a corrosion-resistant alloy, and regions of the monolithic gas distribution assembly that are not exposed to process gases are composed of another alloy that may have a lower cost, a higher mechanical strength, and/or other beneficial property as compared to the corrosion-resistant alloy.

In some embodiments, a gas distribution assembly includes a first portion that is configured to receive a flow of process gas. The first portion may be configured to receive one or more flows of different process gases. The first portion may be disposed at the top of the assembly. In some embodiments, the gas distribution assembly includes a second portion. The second portion and the first portion may together form a first plenum at least partially between the first portion and the second portion. The first plenum may be for receiving the flow(s) of process gas(es) via the first portion. In some embodiments, the first portion forms one or more first gas paths to distribute the flow of process gas into the first plenum. For example, the first portion may form one or more conduits to direct the flow of process gas into the first plenum.

In some embodiments, the gas distribution assembly further includes a third portion. The third portion and the second portion may together form a second plenum at least partially between the second portion and the third portion. In some embodiments, the second portion forms one or more second gas paths to distribute the flow of process gas into the second plenum. For example, the second portion may form one or more conduits to direct the flow of process gas from the first plenum into the second plenum. The one or more second gas paths may be for radially distributing the flow of process gas within the gas distribution assembly. In some embodiments, the third portion forms one or more third gas paths to distribute the flow of process gas from the second plenum into a process chamber. For example, the third portion may form one or more conduits to direct the flow of process gas into the process chamber. In some embodiments, the one or more third gas paths formed by the third portion are to substantially uniformly distribute the flow of process gas within the process chamber.

In some embodiments, the monolithic gas distribution assembly is manufactured via additive manufacturing (e.g., 3D printing). In some embodiments, the first portion, the second portion, and/or the third portion are made by an additive manufacturing process (e.g., by 3D printing, etc.). By utilizing an additive manufacturing process to construct the first portion, the second portion, and/or the third portion, each of the portions can be formed together in a single monolithic body. Additionally, the materials used in the additive manufacturing process can be selected to optimize the corrosion-resistance of the gas distribution assembly, for mechanical strength, and/or for other properties. For example, the gas distribution assembly may be made up of core composed of a first metal alloy (e.g., an aluminum-based alloy such as 6061 aluminum, etc.), while portions of the gas distribution assembly that are exposed to the process gas can be made of a second metal alloy (e.g., a corrosion-resistant metal alloy such as a nickel-based alloy, etc.). In some embodiments, the surface(s) of the first portion, the second portion, and/or the third portion that are exposed to the process gases during operation of the gas distribution assembly are made of a corrosion-resistant metal alloy such as a nickel-based alloy. The metal alloy on these surfaces may react to one or more corrosive gases (e.g., process gases, etc.) to form a corrosion-resistant film on the surfaces that includes the metal alloy. For example, a nickel-based alloy forming the surface of a gas path (e.g., a gas conduit within one of the first portion, the second portion, or the third portion) may react with a fluorine process gas to form a passivation film such as a nickel-fluoride film on the surface. The core of the first portion, the second portion, and/or the third portion that is not exposed to the process gases during operation of the gas distribution assembly may be made of a different metal alloy that may not be corrosion-resistant, such as an aluminum-based metal alloy. The aluminum-based metal alloy may provide reduced cost, lighter weight, better thermal properties (e.g., coefficient of thermal expansion, heat dissipation, thermal conductivity, etc.) than the nickel-based metal alloy. By selectively choosing the material of the gas distribution assembly as described herein, cost can be reduced while increasing the corrosion-resistance of the assembly.

Embodiments of the present disclosure provide advantages over conventional systems described above. Particularly, aspects and implementations of the instant disclosure provide a monolithic gas distribution assembly having integrated components (e.g., integrated into a single monolithic body) and enhanced corrosion-resistance. Some advantages may include reduced assembly and/or maintenance time when compared to conventional solutions by providing a gas distribution assembly having components integrated into a single monolithic body. This may additionally reduce the cost of the gas distribution when compared with conventional assemblies. Additionally, a gas distribution assembly as described herein may have enhanced corrosion-resistance characteristics when compared to conventional assemblies because of the capability to selectively manufacture the assembly with corrosion-resistant metal alloys on the surfaces of the assembly that are exposed to process gases. Moreover, utilizing additive manufacturing process(es) to manufacture a gas distribution assembly described herein allows for the construction of complex internal geometries not otherwise possible. Therefore, in some embodiments, a gas distribution assembly as described herein may more effectively distribute process gas(es) inside a process chamber when compared to conventional solutions, leading to more accurate and/or more consistent substrate processing.

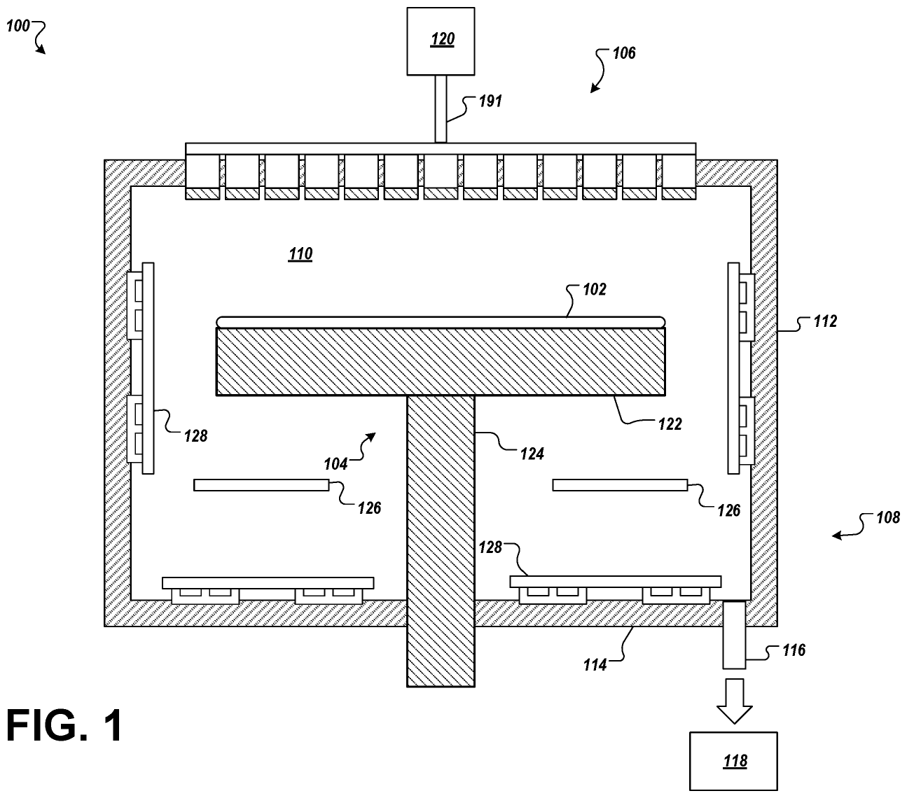

FIG. 1 depicts a sectional view of a process chamber 100 (e.g., a semiconductor processing chamber) according to some aspects of this disclosure. Process chamber 100 may be one or more of an etch chamber (e.g., a plasma etch chamber), deposition chamber (including atomic layer deposition, chemical vapor deposition, physical vapor deposition, or plasma enhanced versions thereof), anneal chamber, or the like. For example, process chamber 100 may be a chamber for a plasma etcher, a plasma cleaner, atomic layer deposition (ALD) device, chemical vapor deposition (CVD) device, and so forth. Examples of chamber components may include a substrate support assembly 104, an electrostatic chuck, a ring (e.g., a process kit ring), a chamber wall, a base, a gas distribution assembly 106, a liner, a liner kit, a shield, a plasma screen, a flow equalizer, a cooling base, a chamber viewport, a chamber lid, a nozzle and so on.

In one embodiment, process chamber 100 may include a chamber body 108 and a gas distribution assembly 106 that enclose an interior volume 110. In some chambers, gas distribution assembly 106 may be replaced by a lid and a nozzle. Chamber body 108 may be constructed from aluminum, stainless steel, or other suitable material. Chamber body 108 generally includes sidewalls 112 and a bottom 114.

An exhaust port 116 may be defined in chamber body 108, and may couple interior volume 110 to a pump system 118. Pump system 118 may include one or more pumps and valves utilized to evacuate and regulate the pressure of interior volume 110 of process chamber 100. An actuator to control gas flow out of the chamber and/or pressure in the chamber may be disposed at or near exhaust port 116.

Gas distribution assembly 106 may be supported on sidewalls 112 of chamber body 508 or on a top portion of the chamber body. Gas distribution assembly 106 (or the lid, in some embodiments) may be opened to allow access to interior volume 110 of process chamber 100, and may provide a seal for process chamber 100 while closed.

Gas panel 120 may be coupled to process chamber 100 via one or more gas delivery lines (also referred to as supply lines) 191 to provide process or cleaning gases to interior volume 110 through gas distribution assembly 106 (or lid and nozzle). The gas panel 120 may be coupled to the process chamber 100 to provide process and/or cleaning gases via one or more supply lines to the interior volume 110 through gas distribution assembly 106.

The gas panel 120 may include or be connected to one or more flow control apparatus. The flow control apparatus(es) may be used to measure and control the flow of one or more gasses from one or more gas sources to interior volume 110. In one embodiment, the gas panel 120 includes multiple gas stick assemblies. Each gas stick assembly may include one or more valves, filters, mass flow controllers (MFCs) and/or other components.

Gas distribution assembly 106 may include multiple gas delivery holes throughout. Examples of processing gases that may be used to process substrates in process chamber 100 may include toxic gases, non-toxic gases, or a combination thereof. For example, the processing gases may include halogen-containing gases, such as C₂F₆, SF₆, SiCl₄, HBr, NF₃, CF₄, CHF₃, F₂, Cl₂, CCl₄, BCl₃, and SiF₄, among others, and other gases such as O₂ or N₂O. Examples of carrier gases include N₂, He, Ar and other gases inert to process gases (e.g., non-reactive gases).

In some embodiments, gas distribution assembly 106 includes multiple portions (e.g., a first portion, a second portion, a third portion, etc.) that together form a single monolithic body. In some embodiments, the gas distribution assembly 106 is manufactured by one or more additive manufacturing processes. In some embodiments, internal surfaces of the gas distribution assembly 106 that exposed flow process gas(es) are made of a corrosion-resistant metal alloy such as a nickel-based alloy. The core of the gas distribution assembly may be made of a non-corrosion-resistant metal alloy such as an aluminum-based alloy.

Substrate support assembly 104 may be disposed in interior volume 110 of process chamber 100 below gas distribution assembly 106. In some embodiments, substrate support assembly 104 includes a susceptor 122 and shaft 124. Substrate support assembly 104 supports a substrate during processing. In some embodiments, also disposed within process chamber 100 are one or more heaters 126 and reflectors 128.

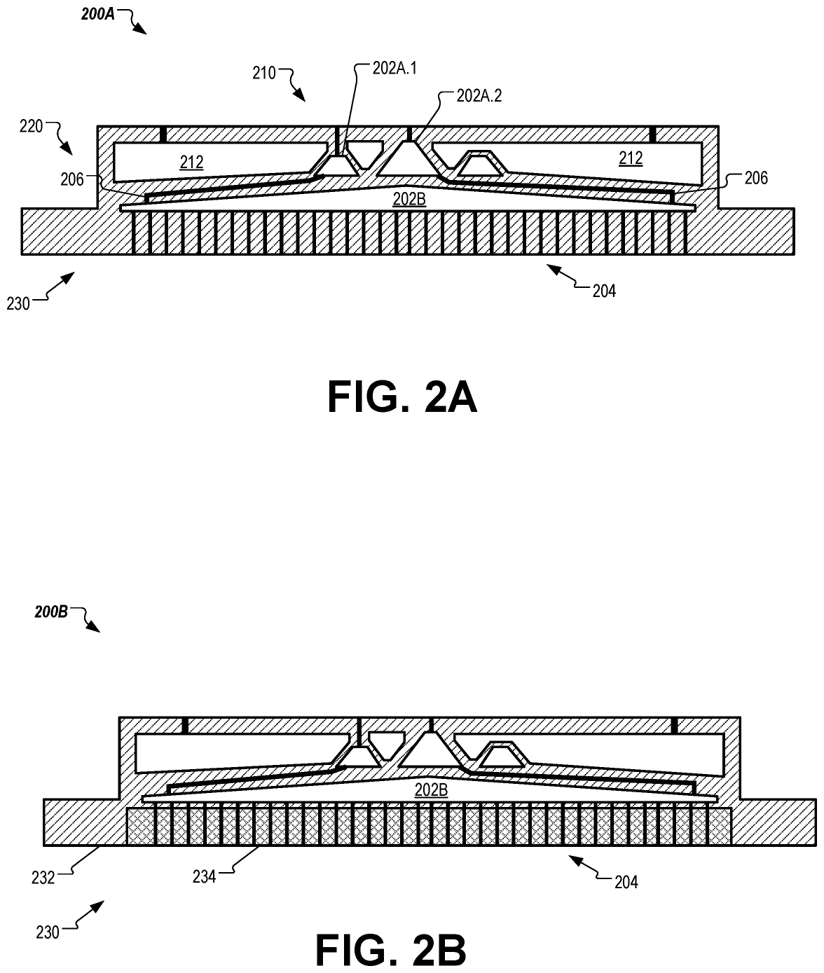

FIG. 2A depicts a monolithic gas distribution assembly 200A, according to certain embodiments of the present disclosure. In some embodiments, the gas distribution assembly 200A may correspond to gas distribution assembly 106 of FIG. 1. In some embodiments, assembly 200A includes a gas box 210 (e.g., a first portion), a blocker plate 220 (e.g., a second portion), and a showerhead 230 (e.g., a third portion). In some embodiments, the gas distribution assembly 200A is configured to receive one or more process gases and distribute the process gases within a process chamber.

In some embodiments, the gas box 210 forms one or more conduits that are to receive a flow of process gas (e.g., from gas panel 120). The flow of a first process gas may be introduced through the conduit(s) into a first upper plenum 202A.1 while the flow of a second process gas may be introduced through the conduit(s) into a second upper plenum 202A.2. In some embodiments, each of the upper plenums may be formed at least partially between the gas box 210 and the blocker plate 220. In some embodiments, the gas box 210 forms one or more chambers 212 through which liquid coolant can flow to cool the assembly 200A.

In some embodiments, the blocker plate 220 forms one or more gas conduits 206 to flow process gas(es) from the first upper plenum 202A.1 and the second upper plenum 202A.2 to a lower plenum 202B. In some embodiments, the lower plenum 202B is formed at least partially between the blocker plate 220 and the showerhead 230. The gas conduits 206 may radially distribute the process gas(es) within the assembly 200A. In some embodiments, multiple process gases are introduced into the lower plenum 202B and are mixed within the lower plenum 202B.

In some embodiments, the showerhead 230 forms multiple gas outlets 204 that are to distribute process gases substantially uniformly within a process chamber. Although the multiple gas outlets 204 are shown in FIG. 2A having a straight and upright orientation, the gas outlets 204 may have a different orientation. For example, the gas outlets 204 may have an angled orientation, may not be straight, may be split, may be horizontal, etc.

In some embodiments, the gas box 210, the blocker plate 220, and/or the showerhead 230 form a single monolithic body. In some embodiments, a core of the gas box 210, the blocker plate 220, and/or the showerhead 230 are formed from a first metal alloy. The interior surfaces of the gas box 210, the blocker plate 220, and/or the showerhead 230 that are exposed to process gases may be formed from a protective layer that includes a second metal alloy that is corrosion-resistant. The protective layer and the core may be manufactured together via additive manufacturing of the monolithic body. In some embodiments, surfaces exposed to the process gas during operation of the assembly 200A include surfaces of the plenums and/or surfaces of the gas paths. For example, the surfaces of the first upper plenum 202A.1, the second upper plenum 202A.2, the gas conduits 206, the lower plenum 202B, and/or the gas outlets 204 may be made of a corrosion-resistant metal alloy such as a nickel-based alloy while the remainder of the assembly 200A is formed of a non-corrosion-resistant metal alloy such as an aluminum-based alloy. In some embodiments, the second metal alloy that is corrosion-resistant forms a layer that is approximately 10 μm to 5 mm thick. For example, the nickel-based alloy layer forming the surfaces exposed to process gas may be approximately 10 μm to 5 mm thick. During operation of the assembly 200A, the second metal alloy forming the protective layer may react with process gas to form a corrosion-resistant film. For example, a nickel-based alloy on the interior surfaces of the gas box 210, the blocker plate 220, and/or the showerhead 230 may react with a fluorine process gas to form a nickel-fluoride film. The nickel-fluoride film may be substantially corrosion-resistant.

In some embodiments, the method of additive manufacturing for the gas distribution assembly 200A can include one, or any combination of, ultrasonic additive manufacturing (UAM), selective laser sintering (SLS), selective laser melting (SLM), electron beam melting (EBM), binder jetting (BJ), material jetting (MJ), or any other similar method of metallic additive manufacturing. In embodiments, the gas distribution assembly can be manufactured in any orientation feasible (e.g., horizontal, vertical, or any orientation with respect to the gas distribution assembly, etc.).

In some embodiments, the material that the gas distribution assembly 200A is made out of (as discussed above) can include a metal that is initially in the form of a powder or a sheet. The powder or sheet may include, but is not limited to, stainless steel alloy(s), aluminum, aluminum alloy(s), titanium, titanium alloy(s), cobalt chrome alloy(s), nickel alloy(s), or any other type or metal or metal alloy commonly used in metallic additive manufacturing.

FIG. 2B depicts a monolithic gas distribution assembly 200B, according to certain embodiments of the present disclosure. In some embodiments, gas distribution assembly 200B includes substantially the same features as gas distribution assembly 200A. In some embodiments, showerhead 230 is made up of an inner portion 234 and an outer portion 232. The outer portion 232 may be made substantially of a first material and the inner portion 234 may be made substantially of a second material different from the first material. For example, the inner portion 234 may be made of a nickel-based alloy while the outer portion 232 may be made of an aluminum-based alloy. In some embodiments, the inner portion 234 at least partially forms the gas outlets 204. The inner portion 234 may form the region of the showerhead 230 beneath the lower plenum 202B. In some embodiments, the inner portion 234 can be reconditioned and/or replaced after a threshold amount of corrosion. For example, after the gas outlets 204 and/or the lower surface of the inner portion 234 corrode to a point where substrate processing is negatively affected, the inner portion 234 can be reconditioned to restore the inner portion 234 to an original condition.

In some embodiments, after the inner portion 234 (and/or the gas outlets 204) are corroded, the inner portion 234 can be removed from the outer portion 232. A milling operation or other material removal operation may be performed to remove the inner portion 234. In some embodiments, after removal of the inner portion 234, a new inner portion 234 may be added to the showerhead 230. In some embodiments, the new inner portion is added within the outer portion 232 by an additive manufacturing operation. The additive manufacturing operation may build up the new inner portion 234 within the outer portion 232 layer by layer until the new inner portion 234 is complete. In some embodiments, the new inner portion 234 is a pre-fabricated part that is interfaced into the empty space within the outer portion 232. The new inner portion may at least partially form new gas outlets 204. The process of removing and replacing the inner portion 234 can be repeated at least several times.

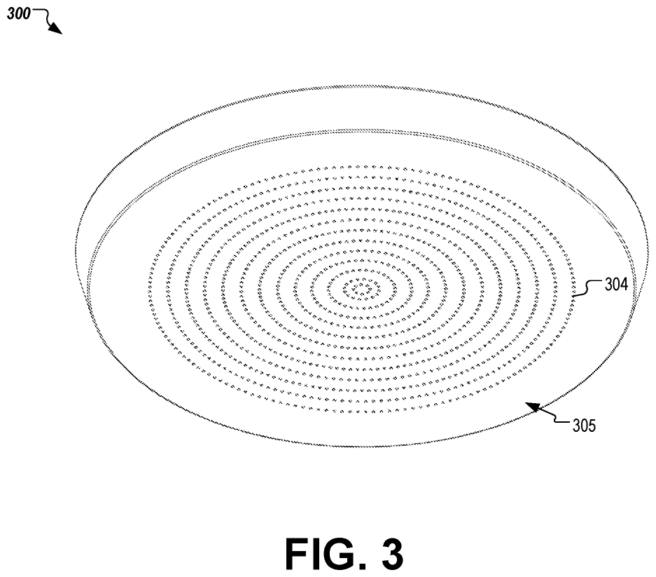

FIG. 3 illustrates one embodiment of a bottom perspective view of a showerhead 300. In some embodiments, the showerhead 300 corresponds to showerhead 230 of gas distribution assemblies 200A and 200B. The showerhead 300 may have a series of gas conduits 304 (also referred to as holes) arranged concentrically that evenly distribute process plasma and process gasses directly over a substrate or wafer to be etched or processed (e.g., material deposition process or another process, etc.). The showerhead is depicted here having approximately 1100 gas conduits 304 arranged in evenly distributed concentric rings for even distributing of gasses. In another embodiment, the gas conduits 304 may be configured in alternative geometric configurations on the lower surface 305 of the showerhead (or on a lower surface of a GDP bonded to a showerhead). For example, the showerhead may have a square or rectangular configuration having rows and columns of gas conduits 304. It is to be understood that other shapes (e.g., triangle, pentagon, etc.) may be implemented. The showerhead 300 can have many gas conduits 304, as depicted, or as few gas conduits as appropriate depending on the type of reactor and/or process utilized. In embodiments, the showerhead 300 is a 3D printed part.

In one embodiment, some or all gas conduits 304 do not include branches (e.g., each gas conduit may have a single entry point and a single exit point). Additionally, the gas conduits may have various lengths and orientation angles. Gas may be delivered to the gas conduits 304 via one or more gas delivery nozzles. Some gas conduits 304 may receive the gas before other gas conduits 304 (e.g., due to a proximity to a gas delivery nozzle). In some embodiments, one or more gas conduits 304 include branches, changing internal diameters (e.g., an upper via having a smaller diameter and a lower via having a larger diameter, or vice versa, etc.), changes in direction, and/or other internal features that would be impractical to form via traditional manufacturing processes. In embodiments, the complex internal features of the showerhead 300 are achieved via 3D printing of the showerhead 300. The gas conduits 304 may be configured to deliver gas to a substrate resting beneath the showerhead at approximately the same time based on varying the orientation angles, diameters and/or lengths of the gas conduits 304, or by using an additional flow equalizer in embodiments. For example, gas conduits 304 that will receive gas first may be longer and/or have a greater angle (e.g., an angle that is further from 90 degrees) than conduits that will receive gas later.

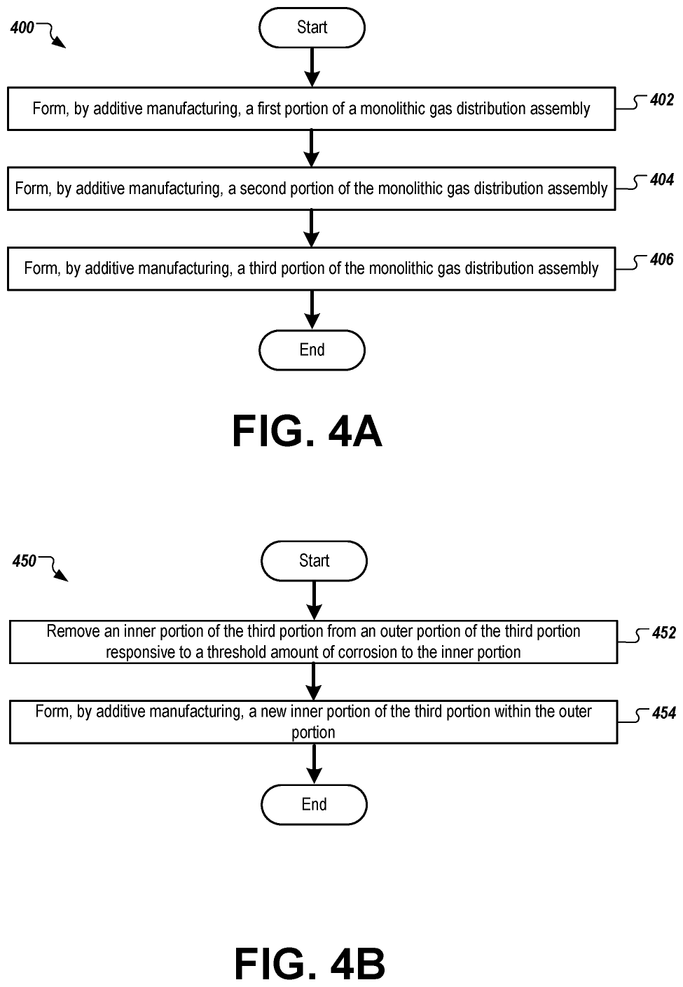

FIG. 4A illustrates a flow chart of a method 400 for manufacturing a monolithic gas distribution assembly, according to certain embodiments of the present disclosure. In some embodiments, operations of method 400 are performed by one or more systems for performing an additive manufacturing operation to construct a monolithic gas distribution assembly as described herein.

At block 402, a first portion (e.g., a gas box 210) of a monolithic gas distribution assembly is formed by additive manufacturing. The first portion may be formed by printing a material layer-by-layer. In some embodiments, the first portion is made up of a first metal alloy and/or a second metal alloy. The first metal alloy may be used to form a core of the first portion and the second metal alloy may be used to form the surface(s) of one or more interior passages and/or cavities of the first portion that are to be exposed to process gas during operation of the gas distribution assembly. The first metal alloy may be a non-corrosion resistant metal alloy and the second metal alloy may be a corrosion-resistant metal alloy.

At block 404, a second portion (e.g., a blocker plate 220) of the monolithic gas distribution assembly is formed by additive manufacturing. The second portion may be formed by printing material layer-by-layer on the first portion. In some embodiments, the second portion is made up of the first metal alloy and/or the second metal alloy. The first metal alloy may be used to form a core of the second portion and the second metal alloy may be used to form the surface(s) of one or more interior passages and/or cavities of the second portion that are to be exposed to process gas during operation of the gas distribution assembly.

At block 406, a third portion (e.g., a showerhead 230) of the monolithic gas distribution assembly is formed by additive manufacturing. The third portion may be formed by printing material layer-by-layer on the second portion. In some embodiments, the third portion is made up of the first metal alloy and/or the second metal alloy. The first metal alloy may be used to form a core of the third portion and the second metal alloy may be used to form the surface(s) of one or more interior passages and/or cavities of the third portion that are to be exposed to process gas during operation of the gas distribution assembly.

FIG. 4B illustrates a flow chart of a method 450 for re-conditioning a monolithic gas distribution assembly, according to certain embodiments of the present disclosure. In some embodiments, operations of method 450 are performed by one or more systems for reconditioning a monolithic gas distribution assembly as described herein.

At block 452, an inner portion (e.g., inner portion 234) of the third portion (e.g., showerhead 230) is removed from an outer portion (e.g., outer portion 232) of the third portion. The removal of the inner portion may be responsive to the inner portion experiencing a threshold amount of corrosion. In some embodiments, the amount of corrosion to the inner portion may be determined based on inspection of the inner portion (e.g., by visual inspection, by inspection sensor readings, etc.) and/or based on substrate process results. The corrosion may be corrosion to gas conduits and/or corrosion to one or more surfaces of the inner portion. In some embodiments, the inner portion is removed from the outer portion by a material removal operation such as by a milling operation. The material removal operation may leave only the outer portion of the third portion intact. In some embodiments, the material removal operation removes the material forming the gas conduits from the third portion. In some embodiments, the inner portion is made of a nickel-based alloy and the outer portion is made of an aluminum-based alloy.

At block 454, a new inner portion of the third portion is formed by additive manufacturing within the outer portion. In some embodiments, the new inner portion is printed layer-by-layer within the outer portion. In some embodiments, the new inner portion includes one or more new gas conduits for distributing process gas inside a process chamber. After the new inner portion is formed, the third portion may be in a condition substantially matching the original condition of the third portion as originally-manufactured. In some embodiments, blocks 452 and 454 can be repeated multiple times over the lifetime of the monolithic gas distribution assembly.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner. In one embodiment, multiple metal bonding operations are performed as a single operation.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A monolithic gas distribution assembly, comprising:
a first portion configured to receive a flow of process gas;
a second portion forming a first plenum at least partially between the first portion and the second portion, wherein the first portion forms one or more first gas paths to distribute the flow of process gas into the first plenum; and
a third portion forming a second plenum at least partially between the second portion and the third portion, wherein the second portion forms one or more second gas paths to distribute the flow of process gas from the first plenum into the second plenum, and wherein the third portion further forms one or more third gas paths to distribute the flow of process gas from the second plenum into a process chamber, wherein the first portion, the second portion, and the third portion form a single monolithic body.

2. The monolithic gas distribution assembly of claim 1, wherein at least one of the first portion, the second portion, or the third portion comprises a core composed of a first metal alloy and a protective layer comprising a second metal alloy that is corrosion-resistant, and wherein the protective layer is at a surface that is exposed to process gases during operation of the gas distribution assembly.

3. The monolithic gas distribution assembly of claim 2, wherein the protective layer comprises a corrosion-resistant film comprising the second metal alloy.

4. The monolithic gas distribution assembly of claim 2, wherein the surface that is exposed to the process gases during operation of the gas distribution assembly comprises one or more of a surface of the first plenum, a surface of the second plenum, surfaces of the one or more first gas paths, surfaces of the one or more second gas paths, or surfaces of the one or more third gas paths.

5. The monolithic gas distribution assembly of claim 2, wherein the first metal alloy comprises an aluminum-based alloy and the second metal alloy comprises a nickel-based alloy.

6. The monolithic gas distribution assembly of claim 1, wherein the third portion comprises an inner portion and an outer portion, wherein the inner portion is configured to be reconditioned after a threshold amount of corrosion.

7. The monolithic gas distribution assembly of claim 6, wherein the inner portion comprises a first metal alloy and the outer portion comprises a second metal alloy different from the first metal alloy.

8. The monolithic gas distribution assembly of claim 1, wherein the second portion is configured to radially distribute the process gas within at least the second plenum, and wherein the third portion is configured to distribute the process gas substantially uniformly within the process chamber.

9. A method, comprising:
forming, by additive manufacturing, a first portion of a gas distribution assembly, wherein the first portion forms one or more first gas paths;
forming, by additive manufacturing, a second portion of the gas distribution assembly, wherein the second portion at least partially forms a first plenum between the first portion and the second portion, and wherein the second portion forms one or more second gas paths; and
forming, by additive manufacturing, a third portion of the gas distribution assembly, wherein the second portion at least partially forms a second plenum between the third portion and the second portion, wherein the third portion forms one or more third gas paths, and wherein the first portion, the second portion, and the third portion form a single monolithic body.

10. The method of claim 9, wherein at least one of the first portion, the second portion, or the third portion are formed by additive manufacturing.

11. The method of claim 9, wherein at least one of the first portion, the second portion, or the third portion comprises a core composed of a first metal alloy and a protective layer comprising a second metal alloy that is corrosion-resistant, and wherein the protective layer is at a surface that is exposed to process gases during operation of the gas distribution assembly.

12. The method of claim 11, wherein the protective layer comprises a corrosion-resistant film comprising the second metal alloy.

13. The method of claim 11, wherein the surface that is exposed to process gases during operation of the gas distribution assembly comprises one or more of a surface of the first plenum, a surface of the second plenum, surfaces of the one or more first gas paths, surfaces of the one or more second gas paths, or surfaces of the one or more third gas paths.

14. The method of claim 11, wherein the first metal alloy comprises an aluminum-based alloy and the second metal alloy comprises a nickel-based alloy.

15. The method of claim 9, further comprising:
removing an inner portion of the third portion from an outer portion of the third portion responsive to a threshold amount of corrosion to the inner portion; and
forming, by additive manufacturing, a new inner portion of the third portion within the outer portion.

16. The method of claim 15, wherein the inner portion comprises a first metal alloy and the outer portion comprises a second metal alloy different from the first metal alloy.

17. A process chamber, comprising:
a gas distribution assembly comprising a single monolithic body having a plurality of integrated components, wherein the plurality of integrated components form at least one interior plenum and multiple gas paths configured to receive one or more process gases and distribute the one or more process gases substantially uniformly within the process chamber.

18. The process chamber of claim 17, wherein at least one of the plurality of integrated components comprise a core composed of a first metal alloy and a protective layer comprising a second metal alloy that is corrosion-resistant, and wherein the protective layer is at a surface that is exposed to process gases during operation of the gas distribution assembly.

19. The process chamber of claim 18, wherein the protective layer comprises a corrosion-resistant film comprising the second metal alloy.

20. The process chamber of claim 18, wherein the surface that is exposed to the process gases during operation of the gas distribution assembly comprises one or more of a surface of the at least one interior plenum or surfaces of the multiple gas paths.
